(19) United States
(12) Patent Application Publication
(10) Pub. No.: US 2026/0282710 A1
(43) Pub. Date: Sep. 17, 2026

(54) Title: DISPLAY DEVICE AND METHOD FOR MANUFACTURING DISPLAY DEVICE

(71) Applicant: Sharp Display Technology Corporation, Kameyama City, Mie (JP)

(72) Inventor: Masayuki KANEHIRO, Kameyama City (JP)

(21) Appl. No.: 19/470,991

(22) PCT Filed: Apr. 4, 2023
(86) PCT No.: PCT/JP2023/013890

§ 371 Date: Sep. 30, 2025

(51) Int. Cl. H10K 59/80; H10K 50/115; H10K 59/12; H10K 59/35

(52) U.S. Cl. CPC H10K 59/873; H10K 50/115; H10K 59/1201; H10K 59/353

(57) ABSTRACT

A first light-emitting element included in a display device according to the disclosure includes a first lower electrode, a first light-emitting layer including first quantum dots, a first protection layer, and a first upper electrode that are layered in this order from a side of a substrate, and the first light-emitting layer and the first protection layer coincide with each other in a plan view.

### TECHNICAL FIELD

The disclosure relates to a display device and a method for manufacturing the display device.

### BACKGROUND ART

In a method for manufacturing an organic EL display device disclosed in PTL 1, an organic compound layer including a light-emitting layer is patterned using photolithography.

### CITATION LIST

### Patent Literature

PTL 1: JP 2014-123441 A

### SUMMARY

### Technical Problem

When a light-emitting layer including quantum dots is patterned using photolithography, the drive voltage of a display device increases (so-called “increase in voltage”).

### Solution to Problem

A display device according to an aspect of the disclosure includes a substrate, and a first light-emitting element including a first lower electrode, a first light-emitting layer including first quantum dots, a first protection layer, and a first upper electrode that are layered in this order from a side of the substrate. The first light-emitting layer and the first protection layer coincide with each other in a plan view.

A method for manufacturing a display device according to an aspect of the disclosure includes forming a first template layer including a photosensitive resin, patterning the first template layer, forming a first light-emitting layer including first quantum dots, above the patterned first template layer, forming a first protection layer above the first light-emitting layer, and patterning the first light-emitting layer and the first protection layer by removing the first template layer.

A method for manufacturing a display device according to an aspect of the disclosure includes forming a first light-emitting layer including first quantum dots, forming a first protection layer above the first light-emitting layer, forming a first template layer including a photosensitive resin, above the first protection layer, patterning the first template layer, patterning the first light-emitting layer and the first protection layer by performing etching in a state where the patterned first template layer is placed above the first protection layer, and removing the first template layer.

### Advantageous Effects of Disclosure

According to an aspect of the disclosure, a degree of an increase in voltage of a display device can be reduced.

### BRIEF DESCRIPTION OF DRAWINGS

FIG. 1 is a plan view illustrating a configuration example of a display device according to an embodiment of the disclosure.

FIG. 2 is a cross-sectional view illustrating a configuration example of the display device according to the embodiment of the disclosure.

FIG. 3 is a cross-sectional view illustrating a configuration example of the display device according to an embodiment of the disclosure.

FIG. 4 is a cross-sectional view illustrating an example of a method for manufacturing the display device according to an embodiment of the disclosure.

FIG. 5 is a cross-sectional view illustrating the example of the method for manufacturing the display device according to the embodiment of the disclosure.

FIG. 6 is a cross-sectional view illustrating the example of the method for manufacturing the display device according to the embodiment of the disclosure.

FIG. 7 is a cross-sectional view illustrating an example of the method for manufacturing the display device according to an embodiment of the disclosure.

### DESCRIPTION OF EMBODIMENTS

### First Embodiment

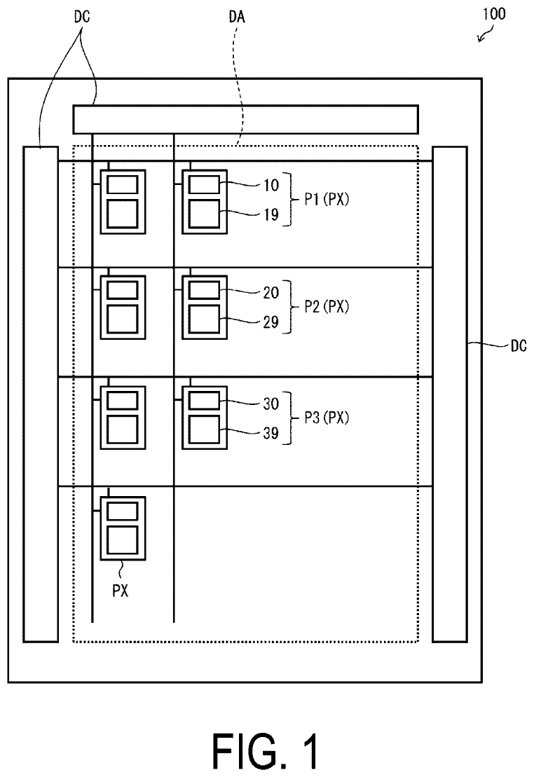

FIG. 1 is a plan view illustrating an example of a configuration of a display device according to an embodiment of the disclosure. As illustrated in FIG. 1, a display device 100 according to the disclosure includes a display portion DA including a plurality of pixels PX, and a drive circuit DC that drives the display portion DA. The plurality of pixels PX include a first pixel P1 including a first light-emitting element 10 and a pixel circuit 19, a second pixel P2 including a second light-emitting element 20 and a pixel circuit 29, and a third pixel P3 including a third light-emitting element 30 and a pixel circuit 39. Hereinafter, particular attention will be paid to the first to third light-emitting elements 10, 20, and 30.

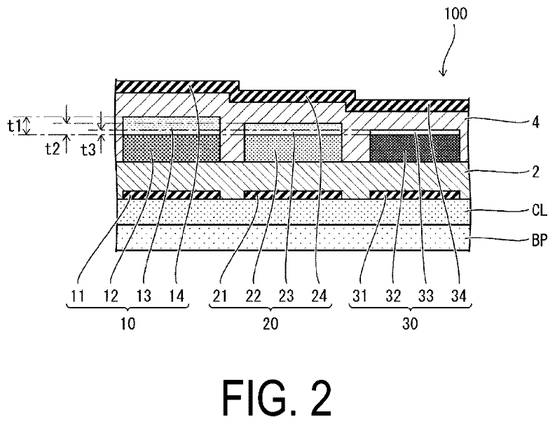

FIG. 2 is a cross-sectional view illustrating a configuration example of the display device according to the embodiment of the disclosure. As illustrated in FIG. 2, the display device 100 according to the disclosure includes a substrate BP, and the first light-emitting element 10 including a first lower electrode 11, a first light-emitting layer 12 including first quantum dots, a first protection layer 13, and a first upper electrode 14 that are layered in this order from a side of the substrate BP. In the first light-emitting element 10, the first light-emitting layer 12 and the first protection layer 13 coincide with each other in a plan view.

According to this configuration, the first light-emitting layer 12 and the first protection layer 13 coincide with each other in a plan view, and thus the first light-emitting layer 12 and the first protection layer 13 can be patterned in the same step. Therefore, during the patterning, the first protection layer is located between a photosensitive resin and the first light-emitting layer 12, and the possibility of the photosensitive resin penetrating into the first light-emitting layer 12 can be reduced. As a result, the degree of increase in voltage of the first light-emitting element 10 and the display device 100 due to the photosensitive resin can be reduced.

One of the first lower electrode 11 and the first upper electrode 14 is an anode and the other is a cathode. At least one of the first lower electrode 11 and the first upper electrode 14 is a light-transmitting electrode, and the other is a light-transmitting electrode or a light-reflecting electrode. The light-reflecting electrode may have a three-layer structure in which silver or a silver alloy is sandwiched between a pair of indium tin oxide layers, or may have a two-layer structure in which indium zinc oxide is layered on aluminum. The light-transmitting electrode may include a light-transmitting metal oxide such as indium tin oxide or indium zinc oxide. The light-transmitting electrode may include a thin film made of a non-light-transmitting conductive material such as magnesium silver and silver and having a thickness that allows light to pass through. The light-transmitting electrode may include silver nanowires.

The first quantum dot included in the first light-emitting layer 12 may have a core-shell structure, a shell-less structure, or a multi-shell structure. The core of the first quantum dot may include any one or more of cadmium selenium, indium phosphorus, zinc selenium, a chalcopyrite-based compound, and a perovskite-based compound.

The first protection layer 13 may be made of an insulating material. The first protection layer 13 may include an insulating resin, and may include, for example, at least one selected from the group consisting of polyvinylpyrrolidone (PVP), polymethyl methacrylate (PMMA), and polyvinyl alcohol (PVA). The first protection layer may include an inorganic insulating material, and may include, for example, alumina. The first protection layer 13 may have resistance to organic solvents, and in particular, it is advantageous that the first protection layer 13 has resistance to at least one of acetone, propylene glycol monomethyl ether acetate (PGMEA), and propylene glycol monomethyl ether (PGME). PVP, PMMA, PVA, and alumina are also examples of materials that are resistant to acetone, PGMEA and PGME.

The thickness of the first protection layer 13 is preferably a thickness sufficient to function as a protection layer and a thickness that allows charge injection from the first upper electrode 14 to the first light-emitting layer 12. For example, the first protection layer 13 may have a thickness of not less than 1 nm and not more than 10 nm, and more preferably, may have a thickness of not less than 2 nm and not more than 8 nm. The first protection layer 13 may function as a buffer layer that adjusts the carrier balance in the first light-emitting layer 12. Typically, it is advantageous for the first upper electrode 14 to be a cathode because electrons are more easily injected than holes.

The first protection layer 13 may be in direct contact with the first light-emitting layer 12. When the first protection layer 13 is in contact with the first light-emitting layer 12, it is advantageous that the first protection layer 13 does not include a material that deteriorates the first light-emitting layer 12. Specifically, the first protection layer 13 includes a material that does not cause the first quantum dots to deteriorate. Furthermore, when the first light-emitting layer 12 includes organic molecules, the first protection layer 13 includes a material that does not cause the organic molecules to deteriorate. The organic molecules included in the first light-emitting layer 12 may be organic ligands protecting the first quantum dots. Further, the first protection layer 13 preferably includes a neutral material, not an acidic material or a basic material. Specifically, the first protection layer 13 preferably includes a material having an acidity of not less than PH6 and not more than PH8. The above-described PVP, PMMA, PVA, and alumina are also examples of materials that do not deteriorate the first quantum dots and the organic molecules.

The display device 100 according to the disclosure may include at least one of a hole injection layer and a hole transport layer as a lower function layer 2 located between the first lower electrode 11 and the first light-emitting layer 12. The display device 100 may include at least one of an electron injection layer and an electron transport layer as an upper function layer 4 located between the first upper electrode 14 and the first protection layer 13. Alternatively, the display device 100 may include at least one of the electron injection layer and the electron transport layer as the lower function layer 2, and may include at least one of the hole injection layer and the hole transport layer as the upper function layer 4.

The hole injection layer may include any one or more of PEDOT:PSS, nickel oxide, nickel oxide nanoparticles, and copper thiocyanate (CuSCN). When the hole injection layer includes an oxide, the surface of the hole injection layer may be covered with a self-assembled monolayer (SAM), and the SAM may include any one or more of 2PACz, MeO—2PACz, Br—PACz, and FOPA. The hole transport layer may include TFB, p-TPD, and PVK. The electron transport layer may include any one or more of zinc oxide nanoparticles and magnesium zinc oxide nanoparticles. When the hole injection layer is provided between the first lower electrode 11 and the first light-emitting layer 12, it is advantageous that the hole injection layer includes nickel oxide nanoparticles having high resistance to an alkaline solution.

The display device 100 may further include, between the substrate BP and the first lower electrode 11, a circuit layer CL including a thin film transistor and a wiring line. The pixel circuit that controls the first light-emitting element 10 may be provided in the circuit layer CL.

The first light-emitting layer 12 and the first protection layer are patterned. The lower function layer 2 and the upper function layer 4 may be patterned or may not be patterned.

The display device 100 according to the disclosure may further include the second light-emitting element 20 including a second lower electrode 21, a second light-emitting layer 22 including second quantum dots, a second protection layer 23, and a second upper electrode 24 that are layered in this order from the side of the substrate BP. The second light-emitting layer 22 and the second protection layer 23 coincide with each other in a plan view. The second light-emitting layer 22 and the second protection layer 23 are patterned.

The second light-emitting layer 22 does not overlap the first light-emitting layer 12 in a plan view. It is advantageous that the second light-emitting layer 22 is separated from the first light-emitting layer 12 in a plan view. The second protection layer 23 may be made of an insulating material, may have an appropriate thickness, and may be in direct contact with the second light-emitting layer 22, similarly to the first protection layer 13. The lower function layer 2 may be located between the second lower electrode 21 and the second light-emitting layer 22. The upper function layer 4 may be located between the second upper electrode 24 and the second protection layer 23.

The display device 100 according to the disclosure may further include the third light-emitting element 30 including a third lower electrode 31, a third light-emitting layer 32 including third quantum dots, a third protection layer 33, and a third upper electrode 34 that are layered in this order from the side of the substrate BP. The third light-emitting layer 32 and the third protection layer 33 coincide with each other in a plan view. The third light-emitting layer 32 and the third protection layer 33 are patterned.

The third light-emitting layer 32 does not overlap the first light-emitting layer 12 and the second light-emitting layer 22 in a plan view. It is advantageous that the third light-emitting layer 32 is separated from the first light-emitting layer 12 and the second light-emitting layer 22 in a plan view. The third protection layer 33 may be made of an insulating material, may have an appropriate thickness, and may be in direct contact with the third light-emitting layer 32, similarly to the first protection layer 13. The lower function layer 2 may be located between the third lower electrode 31 and the third light-emitting layer 32. The upper function layer 4 may be located between the third upper electrode 34 and the third protection layer 33.

Although FIG. 2 illustrates an example in which each of the first to third lower electrodes 11, 21, and 31 is a pixel electrode, and the first to third upper electrodes 14, 24, and 34 are included in a common electrode, the scope of the disclosure is not limited thereto. An example in which the first to third lower electrodes 11, 21, and 31 are included in a common electrode, and each of the first to third upper electrodes 14, 24, and 34 is a pixel electrode is also included in the scope of the disclosure.

The first to third light-emitting layers 12, 22, and 32 may exhibit different colors from each other, and the first to third protection layers 13, 23, and 33 may have thicknesses corresponding to light emission wavelengths of the corresponding light-emitting layers. Generally, the longer the light emission wavelength of the quantum dot, the easier the electron injection into the quantum dot. For example, the first light-emitting layer 12 is a red light-emitting layer, the second light-emitting layer 22 is a green light-emitting layer, and the third light-emitting layer 32 is a blue light-emitting layer. When the thicknesses of the first protection layer 13, the second protection layer 23, and the third protection layer 33 are respectively defined as a first thickness t1, a second thickness t2, and a third thickness t3, the first thickness >the second thickness>the third thickness (t1>t2>t3) may be satisfied. For example, t1 may be approximately 8 nm, t2 may be approximately 5 nm, and t3 may be approximately 3 nm.

According to this configuration, it is possible to reduce the increase in the voltage of the display device 100 and to adjust the carrier balance in each of the light-emitting elements of different colors. In this configuration, each of the first to third protection layers 13, 23 and 33 may include an insulating resin. The types of the insulating resins included in the first to third protection layers 13, 23, and 33 may be different from each other. Alternatively, each of the first to third protection layers 13, 23, and 33 may include an inorganic insulating material.

### Second Embodiment

Another embodiment of the disclosure will be described below. Further, members having the same functions as those of the members described in the above-described embodiment will be denoted by the same reference numerals and signs, and a description thereof will not be repeated for convenience of description.

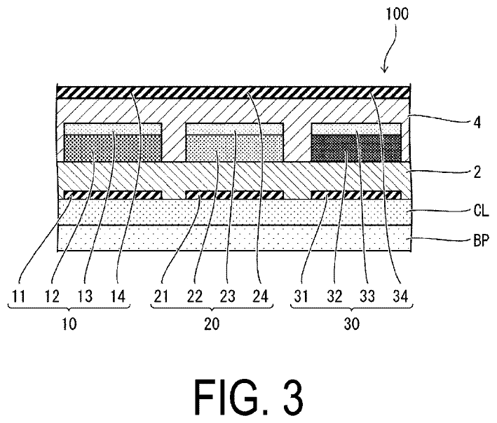

FIG. 3 is a cross-sectional view illustrating a configuration example of the display device according to an embodiment of the disclosure. As illustrated in FIG. 2, the first to third light-emitting layers 12, 22, and 32 may exhibit different colors from each other, and the first to third protection layers 13, 23, and 33 may include insulating resins having average molecular weights corresponding to the light emission wavelengths of the corresponding light-emitting layers. For example, the first light-emitting layer 12 is a red light-emitting layer, the second light-emitting layer 22 is a green light-emitting layer, and the third light-emitting layer 32 is a blue light-emitting layer. When the average molecular weights of the insulating resins included in the first protection layer 13, the second protection layer 23, and the third protection layer 33 are respectively defined as a first molecular weight, a second molecular weight, and a third molecular weight, the first molecular weight>the second molecular weight>the third molecular weight may be satisfied. For example, the first molecular weight may be approximately 360000, the second molecular weight may be approximately 40000, and the third molecular weight may be approximately 10000.

According to this configuration, it is possible to reduce the increase in the voltage of the display device 100 and to adjust the carrier balance in each of the light-emitting elements of different colors. In this configuration, the insulating resins included in the first to third protection layers 13, 23, and 33 may be resins of the same type having different polymerization numbers. Further, the first to third protection layers 13, 23, and 33 may have substantially the same thickness.

Note that the configuration according to the second embodiment can be combined with the configuration according to the first embodiment described above. For example, the first thickness>the second thickness>the third thickness and the first molecular weight>the second molecular weight>the third molecular weight may be satisfied.

### Third Embodiment

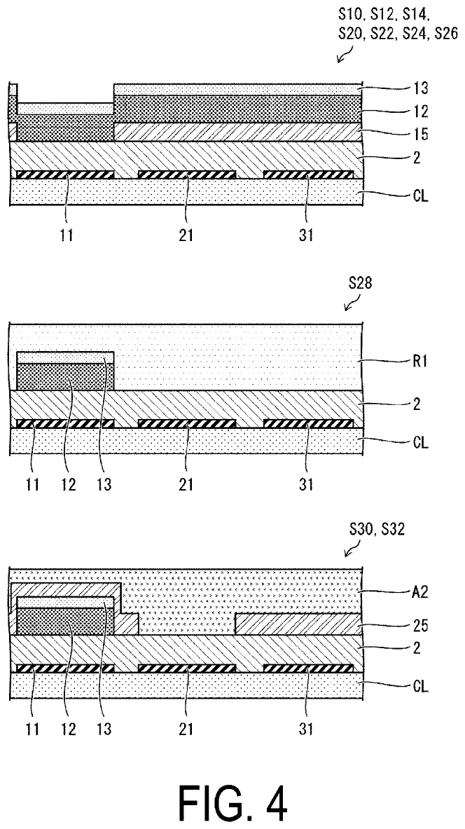

FIGS. 4, 5, and 6 are cross-sectional views illustrating an example of a method for manufacturing the display device according to an embodiment of the disclosure. As illustrated in FIG. 4, the substrate BP and the circuit layer CL are prepared (step S10), and the first to third lower electrodes 11, 21, and 31 are formed (step S12). Subsequently, the lower function layer 2 is formed above the first to third lower electrodes 11, 21, and 31 (step S14). Subsequently, a first template layer 15 including a photosensitive resin is formed above the lower function layer 2 (step S20), and the first template layer 15 is patterned (step S22). The photosensitive resin may be a photosensitive acrylic resin or a photosensitive novolac resin. At step S22, the first template layer 15 is patterned using an alkaline solution. The alkaline solution may include tetramethylammonium hydroxide (TMAH).

Subsequently, the first light-emitting layer 12 including the first quantum dots is formed above the patterned first template layer 15 (step S24), and the first protection layer 13 is formed above the first light-emitting layer 12 (step S26). At step S24, the first light-emitting layer 12 can be formed by applying a solution including the first quantum dots onto the first template layer 15 and drying the coating film. At step S26, a solution including the material of the first protection layer 13 is applied on the first light-emitting layer 12, and the first protection layer 13 can be formed by drying the coating film. The solution may be applied using a slit coater.

Subsequently, by removing the patterned first template layer 15, the first light-emitting layer 12 and the first protection layer 13 are patterned (step S28). At step S28, the first template layer 15 is removed using a removing solution R1 including an organic solvent. At this time, since the first protection layer 13 is exposed to the removing solution R1, it is advantageous that the first protection layer 13 has resistance to the removing solution R1, particularly, resistance to the organic solvent included in the removing solution R1. The organic solvent may include at least one of acetone, PGMEA, and PGME.

At step S28, the first protection layer 13 reduces the elimination and reduction of the organic molecules in the first light-emitting layer 12. Therefore, an increase in exposure of surface defects of the first quantum dots is reduced, and durability and reliability of the display device 100 are improved. Furthermore, in subsequent steps, the photosensitive resin is less likely to adhere to the first light-emitting layer 12.

Subsequently, a second template layer 25 including a photosensitive resin is formed above the first protection layer 13 (step S30), and the second template layer 25 is patterned (step S32). At step S32, the second template layer 25 is patterned using an alkaline solution A2. In order to protect the first light-emitting layer 12 from the alkaline solution A2, it is advantageous to pattern the second template layer 25 so that the second template layer 25 covers the side surfaces of the first light-emitting layer 12. The alkaline solutions A2 may include TMAH.

At step S30, the first protection layer reduces the penetration of the photosensitive resin into the first light-emitting layer 12. Further, although the side surfaces of the first light-emitting layer 12 are in contact with the photosensitive resin, the adhesion of the photosensitive resin to the first light-emitting layer 12 is reduced by the organic molecules in the first light-emitting layer 12.

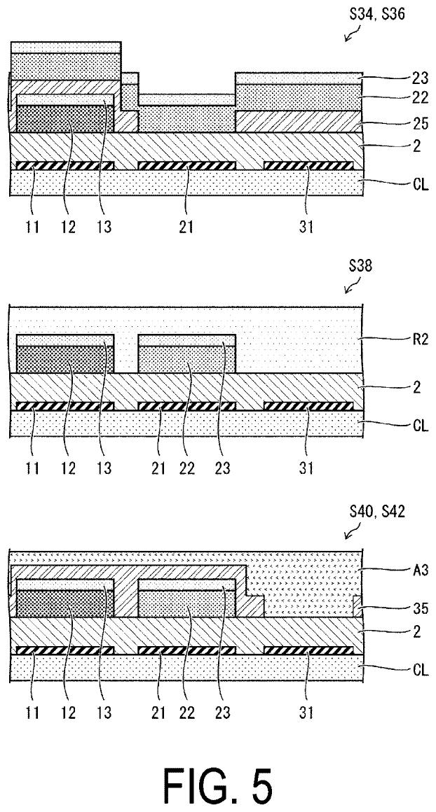

As illustrated in FIG. 5, subsequently, the second light-emitting layer 22 including the second quantum dots is formed on the patterned second template layer 25 (step S34), and the second protection layer 23 is formed above the second light-emitting layer 22 (step S36). Subsequently, by removing the patterned second template layer 25, the second light-emitting layer 22 and the second protection layer 23 are patterned (step S38). At step S38, the second template layer 25 is removed using a removing solution R2 including an organic solvent. At this time, since the first protection layer 13 and the second protection layer 23 are exposed to the removing solution R2, it is advantageous that the first protection layer 13 and the second protection layer 23 have resistance to the removing solution R2, particularly, resistance to the organic solvent included in the removing solution R2. The organic solvent may include at least one of acetone, PGMEA, and PGME.

At step S38, the first protection layer 13 reduces the elimination and reduction of the organic molecules in the first light-emitting layer 12, and the second protection layer 23 reduces the elimination and reduction of the organic molecules in the second light-emitting layer 22. Therefore, an increase in exposure of surface defects of the first quantum dots and the second quantum dots is reduced, and the durability and reliability of the display device 100 are improved. Furthermore, in subsequent steps, the photosensitive resin is less likely to adhere to the first light-emitting layer 12 and the second light-emitting layer 22.

Subsequently, a third template layer 35 including a photosensitive resin is formed above the second protection layer 23 (step S40), and the third template layer 35 is patterned (step S42). At step S42, the third template layer 35 is patterned using an alkaline solution A3. In order to protect the first light-emitting layer 12 and the second light-emitting layer 22 from the alkaline solution A3, it is advantageous to pattern the third template layer 35 so that the third template layer 35 covers the side surfaces of the first light-emitting layer 12 and the second light-emitting layer 22. The alkaline solutions A3 may include TMAH.

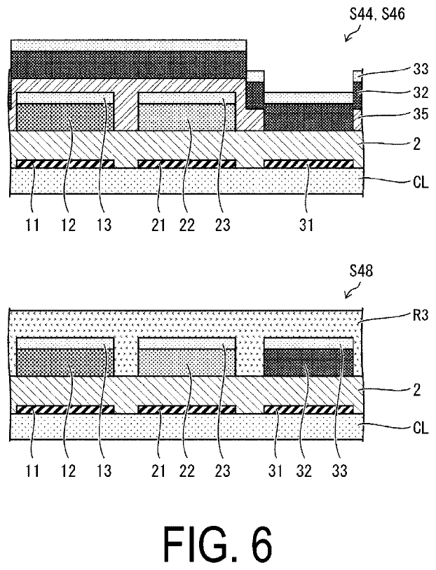

As illustrated in FIG. 6, subsequently, the third light-emitting layer 32 including the third quantum dots is formed above the patterned third template layer 35 (step S44), and the third protection layer 33 is formed above the third light-emitting layer 32 (step S46). Subsequently, by removing the patterned third template layer 35, the third light-emitting layer 32 and the third protection layer 33 are patterned (step S48). At step S48, the third template layer 35 is removed using a removing solution R3 including an organic solvent. At this time, since the first to third protection layers 13, 23, and 33 are exposed to the removing solution R3, it is advantageous that the first to third protection layers have resistance to the removing solution R3, particularly, resistance to the organic solvent included in the removing solution R2. The organic solvent may include at least one of acetone, PGMEA, and PGME.

At step S48, the first protection layer 13 reduces the elimination and reduction of the organic molecules in the first light-emitting layer 12, the second protection layer 23 reduces the elimination and reduction of the organic molecules in the second light-emitting layer 22, and the third protection layer 33 reduces the elimination and reduction of the organic molecules in the third light-emitting layer 32. Therefore, an increase in exposure of surface defects of the first quantum dots, the second quantum dots, and the third quantum dots is reduced, and the durability and reliability of the display device 100 are improved. Furthermore, in subsequent steps, the photosensitive resin is less likely to adhere to the first light-emitting layer 12, the second light-emitting layer 22, and the third light-emitting layer 32.

In this manner, the first light-emitting layer 12 and the first protection layer 13 are patterned in the same step, the second light-emitting layer 22 and the second protection layer 23 are patterned in the same step, and then, the third light-emitting layer 32 and the third protection layer 33 are patterned in the same step by using a so-called “lift-off method”. Subsequently, the upper function layer 4 is formed above the first to third protection layers 13, 23, and 33, and the first to third upper electrodes 14, 24, and 34 are formed above the upper function layer 4.

The lower function layer 2 is exposed to the alkaline solution a plurality of times. Therefore, the lower function layer 2 preferably has high alkali resistance. For example, it is advantageous that the lower function layer 2 includes nickel oxide nanoparticles.

### Comparative Example

As a comparative example, it is assumed that a display device including no protection layer on a light-emitting layer is manufactured. In this comparative example, firstly, since the light-emitting layer is in direct contact with a template layer including a photosensitive resin, the photosensitive resin is likely to penetrate into the light-emitting layer. Secondly, since the light-emitting layer is exposed to an organic solvent for removing the template layer, organic molecules are easily liberated from the light-emitting layer, and the photosensitive resin is easily adhered to the light-emitting layer. Therefore, the deterioration of the light-emitting layer causes a deterioration in durability and reliability of the display device and an increase in voltage of the display device.

According to the method of the disclosure, the photosensitive resin is less likely to penetrate into or adhere to the first to third light-emitting layers 12, 22, and 32, and the organic molecules are less likely to be liberated from the first to third light-emitting layers 12, 22, and 32. Therefore, compared to the comparative example, it is possible to improve the durability and reliability of the display device 100 and to reduce the increase in the voltage of the display device 100.

### Fourth Embodiment

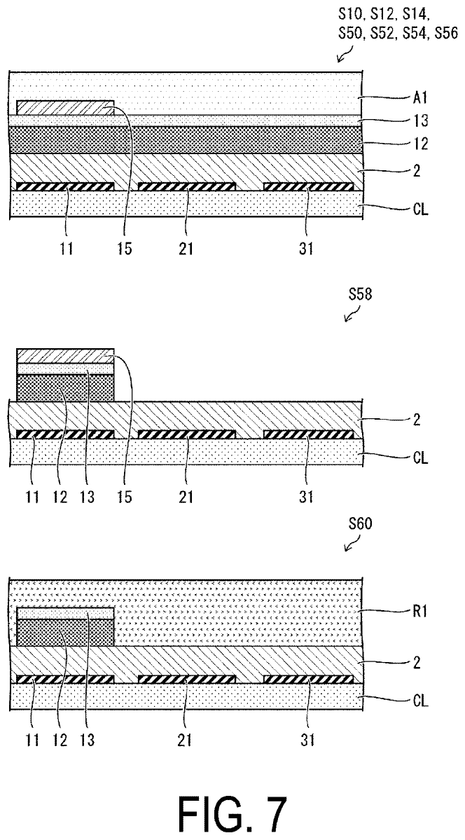

FIG. 7 is a cross-sectional view illustrating an example of a method for manufacturing the display device according to an embodiment of the disclosure. As illustrated in FIG. 7, steps S10, S12, and S14 are performed, and subsequently, the first light-emitting layer 12 including the first quantum dots is formed above the lower function layer 2 (step S50), and the first protection layer 13 is formed above the first light-emitting layer 12 (step S52). Subsequently, the first template layer 15 is formed above the first protection layer 13 (step S54), and the first template layer 15 is patterned (step S56). At step S56, the first template layer 15 is patterned using an alkaline solution A1. The alkaline solutions A1 may include TMAH.

Subsequently, the first light-emitting layer 12 and the first protection layer 13 are patterned by performing etching in a state where the patterned first template layer 15 is placed above the first protection layer 13 (step S 58). Subsequently, the patterned first template layer 15 is removed (step S60). At step S60, the first template layer 15 is removed using the removing solution R1 including the organic solvent. At this time, since the first protection layer 13 is exposed to the removing solution R1, it is advantageous that the first protection layer 13 has resistance to the organic solvent included in the removing solution R1.

Subsequently, the second light-emitting layer 22 and the second protection layer 23 are patterned in the same step, and the third light-emitting layer 32 and the third protection layer 33 are patterned in the same step, by using the lift-off method as in the third embodiment described above. Subsequently, the upper function layer 4 is formed, and the first to third upper electrodes 14, 24 and 34 are formed.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a substrate;
a first light-emitting element including a first lower electrode, a first light-emitting layer including first quantum dots, a first protection layer, and a first upper electrode that are layered in this order from a side of the substrate, the first light-emitting layer and the first protection layer coinciding with each other in a plan view;
a second light-emitting element including a second lower electrode, a second light-emitting layer including second quantum dots, a second protection layer, and a second upper electrode that are layered in this order from the side of the substrate, the second light-emitting layer and the second protection layer coinciding with each other in a plan view; and
a third light-emitting element including a third lower electrode, a third light-emitting layer including third quantum dots, a third protection layer, and a third upper electrode that are layered in this order from the side of the substrate, the third light-emitting layer and the third protection layer coinciding with each other in a plan view,
wherein the first light-emitting layer is a red light-emitting layer, the second light-emitting layer is a green light-emitting layer, and the third light-emitting layer is a blue light-emitting layer, and
the first protection layer, the second protection layer, and the third protection layer have a first thickness, a second thickness, and a third thickness, respectively and the first thickness is greater than the second thickness, and the second thickness is greater than the third thickness, or
the first protection layer, the second protection layer, and the third protection layer include insulating resins having average molecular weights of a first molecular weight, a second molecular weight, and a third molecular weight, respectively and the first molecular weight is greater than the second molecular weight, and the second molecular weight is greater than the third molecular weight.

2. The display device according to claim 1,
wherein the first protection layer is made of an insulating material.

3. The display device according to claim 1,
wherein the first protection layer includes an insulating resin.

4. The display device according to claim 1,
wherein the first protection layer includes one or more selected from the group consisting of polyvinylpyrrolidone (PVP), polymethyl methacrylate (PMMA), and polyvinyl alcohol (PVA).

5. The display device according to claim 1,
wherein the first protection layer includes an inorganic insulating material.

6. The display device according to claim 1,
wherein the first protection layer includes alumina.

7. The display device according to claim 1,
wherein the first protection layer has resistance to organic solvents.

8. The display device according to claim 1,
wherein the first protection layer has resistance to at least one of acetone, propylene glycol monomethyl ether acetate (PGMEA), and propylene glycol monomethyl ether (PGME).

9. The display device according to claim 1,
wherein the first protection layer has a thickness of not less than 1 nm and not more than 10 nm.

10. The display device according to claim 1,
wherein the first protection layer has a thickness of not less than 2 nm and not more than 8 nm.

11-13. (canceled)

14. The display device according to claim further comprising:
a hole injection layer located between the first lower electrode and the first light-emitting layer,
wherein the hole injection layer includes nickel oxide nanoparticles.

15-20. (canceled)

21. The display device according to claim 1,
wherein each of the first protection layer, the second protection layer, and the third protection layer includes an insulating resin.

22. The display device according to claim 1,
wherein each of the first protection layer, the second protection layer, and the third protection layer includes an inorganic insulating material.

23. (canceled)

24. The display device according to claim 1,
wherein the insulating resins included in the first protection layer, the second protection layer, and the third protection layer are resins of the same type having different polymerization numbers.

25. A method for manufacturing a display device, the method comprising:
forming a first template layer including a photosensitive resin;
patterning the first template layer;
forming a first light-emitting layer including first quantum dots, above the patterned first template layer;
forming a first protection layer above the first light-emitting layer; and
patterning the first light-emitting layer and the first protection layer by removing the first template layer.

26. A method for manufacturing a display device, the method comprising:
forming a first light-emitting layer including first quantum dots;
forming a first protection layer above the first light-emitting layer;
forming a first template layer including a photosensitive resin, above the first protection layer;
patterning the first template layer;
patterning the first light-emitting layer and the first protection layer by performing etching in a state where the patterned first template layer is placed above the first protection layer; and
removing the first template layer.

27. The method for manufacturing the display device according to claim 25,
wherein the first template layer is removed using an organic solvent.

28. The method for manufacturing the display device according to any one of claim 25, the method further comprising:
forming a second template layer including a photosensitive resin, above the first protection layer;
patterning the second template layer;
forming a second light-emitting layer including second quantum dots, above the second template layer;
forming a second protection layer above the second light-emitting layer; and
patterning the second light-emitting layer and the second protection layer by removing the patterned second template layer.

29. The method for manufacturing the display device according to claim 28,
wherein the second template layer is patterned using an alkaline solution.

30. The method for manufacturing the display device according to claim 29,
wherein the second template layer is patterned to cover a side surface of the first light-emitting layer.
